(19) United States
(12) Patent Application Publication
(10) Pub. No.: US 2009/0274248 A1
(43) Pub. Date: Nov. 5, 2009

(54) METHOD AND APPARATUS FOR CONTENTION-FREE INTERLEAVING USING A SINGLE MEMORY

(75) Inventors: Edward L. Hepler, Malvern, PA (US); Geetha L. Narayan, Holbrook, NY (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: INTERDIGITAL PATENT HOLDINGS, INC., Wilmington, DE (US)

(21) Appl. No.: 12/428,626

(22) Filed: Apr. 23, 2009

Related U.S. Application Data
(60) Provisional application No. 61/049,552, filed on May 1, 2008.

(51) Int. Cl. H04L 27/06; G11C 29/00

(52) U.S. Cl. 375/341; 714/702

(57) ABSTRACT

A method and apparatus for contention free interleaving are disclosed. A single memory configured to use an address scheme wherein the most significant bits (MSBs) indicate which word in memory stores an interleaved piece of data. The least significant bits (LSBs) are used to calculate an index that identifies a specific soft-in/soft-out (SISO) decoder associated with a sub-word of the retrieved data. Using an interleaved address generator, the extrinsic data may be written into the memory in sequential order, but read out from the memory in interleaved order, effectively de-interleaving the data so it may be decoded. The generated interleaved address is used by SISO selector circuit which controls a multiplexer that routes the sub-word to its appropriate SISO decoder. The same address generator may be used to write interleaved extrinsic data from SISOs by reordering the sub-words, allowing the extrinsic data to be read in sequential order.

### CROSS REFERENCE TO RELATED APPLICATIONS

This application claims the benefit of U.S. provisional application No. 61/049,552 filed May 1, 2008, which is incorporated by reference as if fully set forth.

### FIELD OF INVENTION

This application is related to wireless communications.

### BACKGROUND

The third generation partnership project (3GPP) has prescribed the use of turbo codes for the Long Term Evolution (LTE) project. To speed up decoding, an incoming data block may be divided into smaller sub-blocks that may be decoded in parallel by different decoders. Because some of the bits in the incoming data block are interleaved, the extrinsic data must be interleaved or de-interleaved before it is decoded. Non-parallel decoding using a single decoder requires that the entire data block be de-interleaved before it is decoded. In order to allow for parallel decoding of sub-blocks, the individual sub-blocks must be de-interleaved individually in a contention-free manner.

In U.S. Pat. No. 6,775,800 to Edmonston et al., a conventional method of contention-free de-interleaving is disclosed. The operation of the Edmonston de-interleaver is shown in FIG. 1. An address vector generator 101(a) generates a vector of addresses where a number of addresses are generated that is equal to the number of decoding units being used. The address vector is received by address routing circuit 103(a) while one of the addresses generated is received by the routing selector circuit 105(a). The routing selector circuit 105(a) generates an index associated with the received address and forwards the index to the data routing circuit 107(a) and the address routing circuit 103(a). Using the index generated by the routing selector circuit 105(a), the indexes for the other subsections relating to the other decoder units may be calculated. After receiving the index, the address routing circuit 103(a) generates a second address vector based on the received index and the first address vector. The addresses from the second address vector are then received by N separate extrinsic memories 109₁-109_{N} which in turn output the corresponding data to the data routing circuit 107(a). The data routing circuit 107(a) then routes the data to the correct decoder unit based on the corresponding address based on the index from the routing selector circuit 105(a).

After some processing delay, the decoders generate new extrinsic data that is received by data routing circuit 107(b). As the new extrinsic data is received, address vector generator 101(b) generates the address vector for the interleaver, and the address vector is received by address routing circuit 103(b) and routing selector 105(b) receives one of the addresses. Routing selector 105(b) determines the index for the received address and supplies that index to address routing circuit 103(b) and data routing circuit 107(b). Data routing circuit 107(b) routes the interleaved extrinsic information to the proper extrinsic memory 109₁-109_{N}. Address routing circuit 103(b) routes the address vector to extrinsic memories 109₁-109_{N} as well.

When designing application specific integrated circuits (ASICs), memories are comprised of a core memory array that is surrounded by address coding logic, sense amplifiers, and memory built-in self test (MBIST) circuitry. As a result, using multiple extrinsic memories requires additional overhead and space to accommodate the supporting circuitry for each memory. Accordingly, an interleaver/de-interleaver for a turbo decoder that uses a single extrinsic memory is desirable from the perspective of power requirements and area needed on the chip.

### SUMMARY

A method and apparatus for contention free interleaving are disclosed. A single memory is configured to use an address scheme wherein the most significant bits (MSBs) indicate which word in memory stores an interleaved piece of data. The least significant bits (LSBs) are used to calculate an index that identifies a specific soft-in/soft-out (SISO) decoder that is associated with a sub-word of the retrieved data.

Using an interleaved address generator, the extrinsic data may be written into the memory in sequential order, but read out from the memory in interleaved order, effectively de-interleaving the data so it may be decoded. The generated interleaved address is used by a SISO selector circuit which controls a multiplexer (MUX) that routes the sub-word to its appropriate SISO. The same address generator may be used to write interleaved extrinsic data from SISOs by reordering the sub-words. This allows the extrinsic data to be read in sequential order.

### BRIEF DESCRIPTION OF THE DRAWINGS

A more detailed understanding may be had from the following description, given by way of example in conjunction with the accompanying drawings wherein:

FIG. 1 is a block diagram of a conventional interleaver;

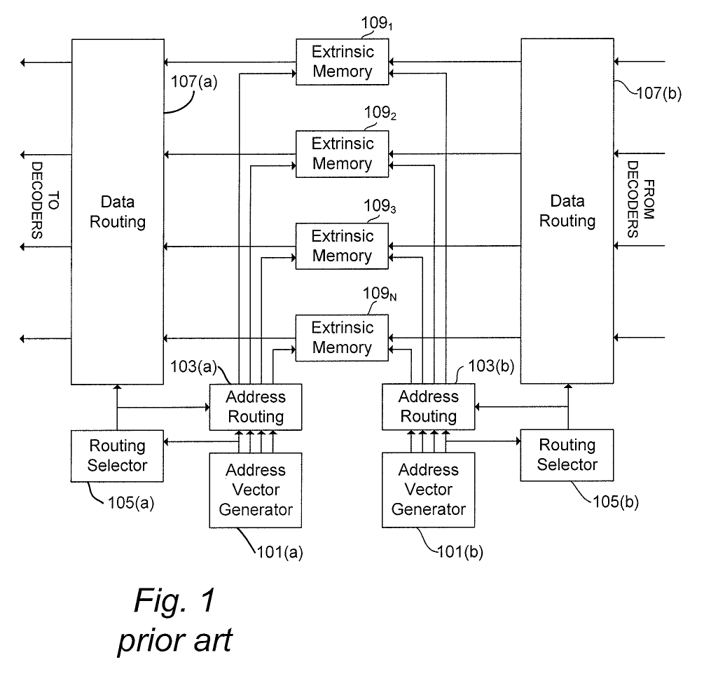

FIG. 2 shows a decoding estimation iteration of a turbo decoder;

FIG. 3 is a block diagram of a decoder using a contention-free de-interleaver using a single memory;

FIG. 4 shows a memory configured for use in a contention free de-interleaver.

FIG. 5 shows a functional diagram of a method interleaved address interleaver;

FIG. 6 shows the hardware portion of an interleaved address generator; and

FIG. 7 shows the hardware portion a SISO selector circuit.

### DETAILED DESCRIPTION

When referred to hereafter, the terminology “wireless transmit/receive unit (WTRU)” includes but is not limited to a user equipment (UE), a mobile station, a fixed or mobile subscriber unit, a pager, a cellular telephone, a personal digital assistant (PDA), a computer, or any other type of user device capable of operating in a wireless environment. When referred to hereafter, the terminology “base station” includes but is not limited to a Node-B, a site controller, an access point (AP), or any other type of interfacing device capable of operating in a wireless environment.

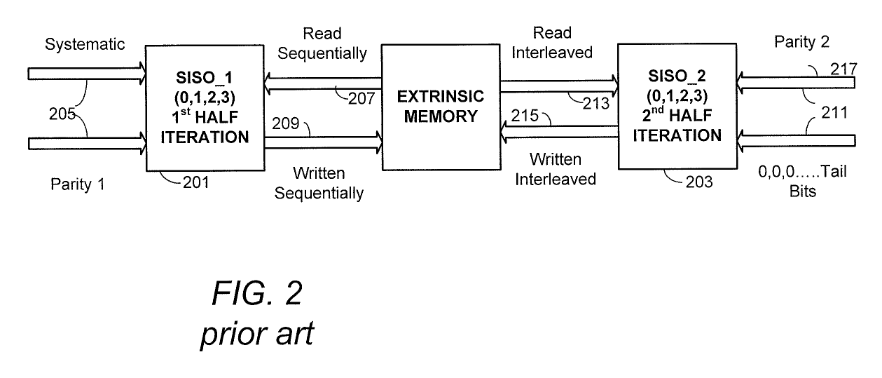

Turbo decoding is an iterative algorithm which takes several passes through the data, improving the estimate of the actual transmitted data on each pass. FIG. 2 shows a single iteration of a turbo decoder. The main component in a Turbo Decoder is the Soft In Soft Out (SISO) block. The SISO block is run repeatedly when decoding data. The output of each SISO is K extrinsic values, which represent the probability that Sₖ was a one or a zero. Each SISO uses the extrinsic values from the other SISO to obtain new extrinsic values. The extrinsic values become more accurate with each iteration. Each iteration may be divided into two steps. SISO_1 201 performs the first step and SISO_2 203 performs the second step. Each time each SISO runs, it uses the extrinsic values from the other SISO. During the first half-iteration, SISO_1 201 uses data from the first encoder 205 and the extrinsic values 215 from SISO_2 203 to generate new extrinsic values 209. During each second half-iteration, SISO_2 203 uses data from the second encoder 211 and the extrinsic values 209 from SISO_1 201 to generate new extrinsic values 215. The extrinsic values become more accurate after each half-iteration. Because the received parity 2 items 217 are interleaved, the extrinsic output of SISO_1 201 is interleaved 213 before SISO_2 203 uses it so that the extrinsic values 209 are associated with the correct parity 2 values 217. For the same reason, the output of SISO_2 203 is de-interleaved 207 before it is input to SISO_1 201.

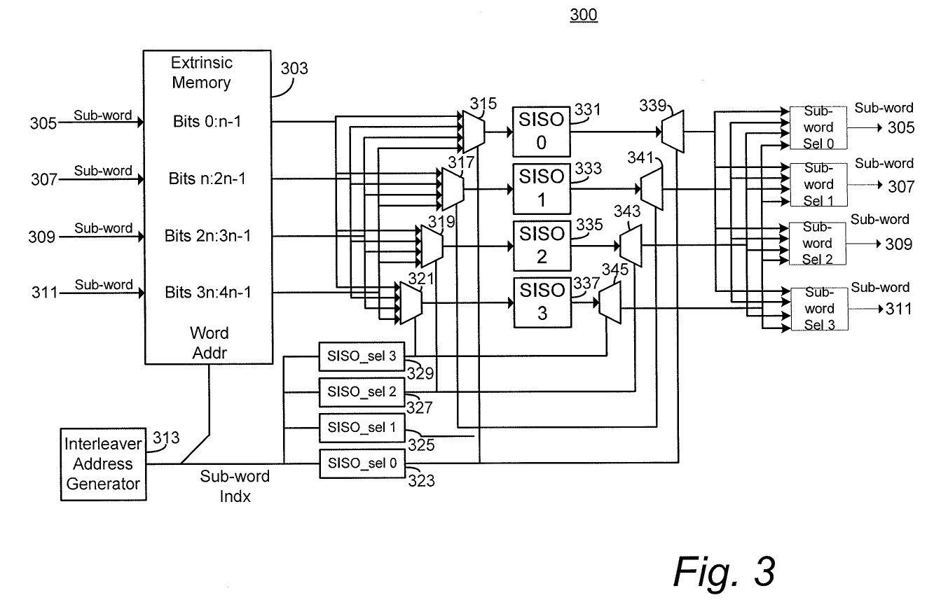

FIG. 3 is a block diagram of a turbo decoder 300 including an interleaver/de-interleaver configured to operate using a single extrinsic memory 303. The decoder 300 receives a block of data is as input. The input code block may be any length, for example, a code block may be 320 bits, but other data block lengths may be used. Each bit of data received was encoded and is represented by a plurality of bits comprising systematic bits, parity 1 bits, and parity 2 bits. When the input was encoded, the bits were also interleaved. In order to decode the input it needs to be de-interleaved before it can be decoded.

When the decoder 300 receives an input, decoding may be performed faster by directing portions of the input to more than one decoding circuit. A soft-in/soft-out (SISO) circuit 331 may be used for decoding. The decoder 300 is configured so that the number of SISOs 331 used is a power of two. In the example shown in FIG. 3, four SISOs 331, 333, 335, and 337 are used to perform decoding. Each SISO 331, 333, 335, 337 decodes a portion of a word stored in single extrinsic memory 303. The word in single extrinsic memory 303 is divided into sub-words 305, 307, 309, 311 which represent the portions of the word that will be directed to a specific SISO 331, 333, 335, 337. Each SISO 331, 333, 335, 337 decodes its associated sub-word portion in parallel with the other SISOs 331, 333, 335, 337 allowing more data to be decoded in a given time period than may be decoded by a single SISO processing all the data in sequence.

To decode the input, the extrinsic data is de-interleaved before it is decoded so the output is decoded in its correct order. As the extrinsic data is received, it is written into single extrinsic memory 303 sequentially, filling single extrinsic memory 303 column-wise. The width of single extrinsic memory 303 is equal to the number of extrinsic bits times the number of SISOs being used. For example, if each extrinsic data bit is represented by 10 encoded bits, and four SISOs are used, the width of the single memory 303 is configured to be 4×10=40 bits. For a 320 bit data block using four SISOs, the number of columns in the memory needed to store the data block is 320 bits/4 SISOs=80 words (columns) to store all the extrinsic words. Therefore, the single memory 303 will be 80 columns, each column being 40 bits wide.

The extrinsic input is written to single extrinsic memory 303 beginning with the first column. When the first column of single extrinsic memory 303 is filled, the column contains a word comprised of sub-words. Each sub-word contains a portion of the word that that will be distributed to one of the SISO decoders 331, 333, 335, 337 based on logic performed by the SISO selector circuits 323, 325, 327, 329. As incoming data is received, it is filled column-by-column in a linear fashion. That is, the first received extrinsic word is stored in memory word 0, the second word is stored in memory word 1 and so on. When 25% of the extrinsic values have been stored in memory 303, the first sub-word 1 will be filled for each word (column) in memory 303. When all the memory addresses for sub-word 1 have been filled, the extrinsic values will then be stored in the sub-word 2 positions in each column in memory 303 and so forth until the entire data block is stored in extrinsic memory 303.

A sub-word 305 comprising the 10 extrinsic bits associated with a single data bit are stored in the first sub-word 305 in the extrinsic memory 303. Sub-words 307, 309, and 311 each also represent 10 encoded bits representing a single data bit are written to single extrinsic memory 303 in a linear fashion.

The input is forwarded to the decoders 331, 333, 335, and 337 in interleaved order. To do this, the data stored in single extrinsic memory 303 must be read from extrinsic memory 303 in interleaved order. The addressing scheme of single extrinsic memory 303 is configured such that the most significant bits (MSBs) of the address represent an interleaved address index generated by interleaved address generator 313. The generated interleaved address index is mapped to a specific word or column in single extrinsic memory 303. The least significant bits (LSBs) of the address in single extrinsic memory 303 are configured to contain a SISO index indicating which of the SISOs 331, 333, 335, and 337 should receive each sub-word contained in the stored word.

Interleaver address generator 313 provides an interleaved address which is used to identify which column in single extrinsic memory 303 should be read and forwarded to each SISO in the decoder. The MSBs of the word address select a word from memory. The LSBs determine which SISO 331, 333, 335, 337 should get each sub-word. Each sub-word is provided as an input to MUX 315, 317, 319, 321. A SISO selector 323, 325, 327, 329 associated with each MUX then controls the output of the MUX 315, 317, 319, 321 and routes each sub-word to its appropriate SISO 331, 333, 335, 337. Each MUX 331, 333, 335, 337 receives four inputs, one input corresponding to each sub-word of the retrieved column in the single memory 303. The interleaver address generator 313 also provides the generated address to four SISO selector circuits 323, 325, 327, 329 each connected to the output control of an associated MUX 315, 317, 319, and 321 respectively.

Based on the LSBs of the address generated by the interleaver address generator 313, the SISO selector circuits 323, 325, 327, and 329 interpret the index corresponding to a specific SISO 331, 333, 335 and 337. Based on the index, the SISO selector circuit 323, 325, 327, and 329 direct the sub-word through one of the MUXs 315,317, 319 or 321 to the SISO 331, 333, 335 or 337 which should receive the sub-word for decoding. For example, when SISO selector 329 receives the address generated from interleaver address generator 313. SISO selector 329 uses the LSBs in the generated interleaver address to determine which sub-word that SISO 337 should receive. SISO selector 329 then sends a control signal to MUX 321 and routes the appropriate sub-word to the SISO 337. The other MUX selector circuits perform the same function on their respective MUXs to route the appropriate sub-word to their corresponding SISO.

After the current iteration occurs, the extrinsic data is used as input for the next turbo decoding iteration. The output is directed to a MUX 339, 341, 343, 345 which receives the SISO address index from SISO selector circuits 323, 325, 327, 329 as an output control. The output from the SISO 3331, 333, 335, 337 are directed through MUXs 339, 341, 343, 345 to the appropriate sub-word 305, 307, 309, 311 to be stored in extrinsic memory 303 for the next decoding iteration.

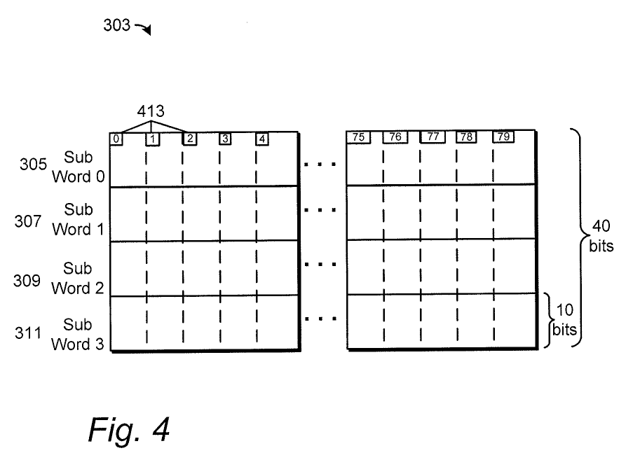

FIG. 4 shows the configuration of a memory cell 303 designed to be used with a contention-free de-interleaver using a single memory, four SISOs and a 320 bit data block. The memory cell 303 is configured to store 80 words. Each word may be viewed as a column 0 to 79 413. Within each word (column) 413 there are four sub-words 305, 307, 309, and 311. Each sub-word 305, 307, 309, 311 is configured to contain one data bit represented by 10 extrinsic bits. Based on a decoder using four SISOs, there are four sub-words of 10 bits making up each word or column. Therefore, each word is 40 bits wide. When data is received from the SISOs after de-interleaving, the data is stored sequentially as it is received. Each sub-word 305, 307, 309, 311 is provided with its own write enable to allow the memory 303 to be written by sub-word.

The memory addresses in the memory 303 are configured such that the MSBs of the memory address denote the word or column containing the next interleaved data. The LSBs in the memory address are used to determine which SISO should receive each sub-word in the interleaved word. When the data is read, the MSBs indicate which column to retrieve. The whole word is retrieved from the column. Each sub-word in the retrieved word is sent to four MUXs, one MUX is provided for each SISO used for decoding. A MUX selector circuit uses the LSBs of the address generated by the interleaver address generator to determine which SISO should get a particular sub-word and routes the correct sub-word through the MUX to the SISO.

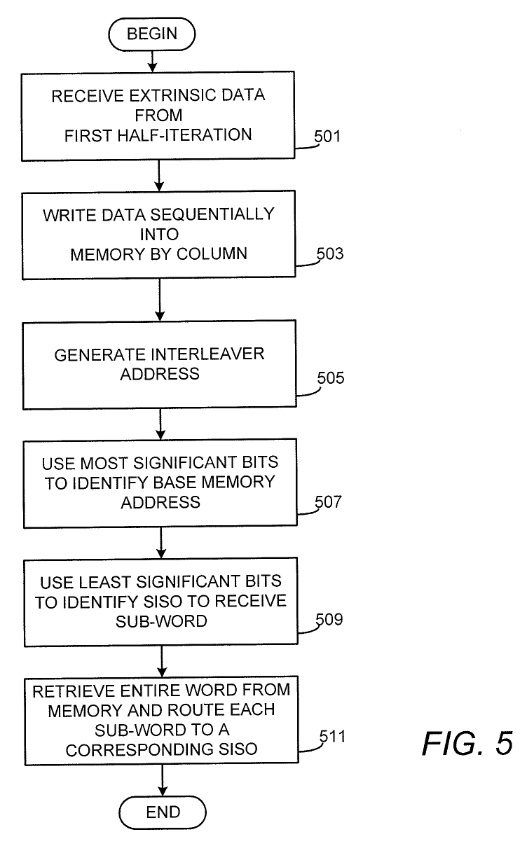

FIG. 5 is a block diagram of a method of interleaving extrinsic data using a single extrinsic memory 303. Sequential extrinsic data is received by the decoder from the first half of the iteration 501. As the data is received, each received bit of data is represented by a plurality of encoded bits. As the extrinsic bits are received, they are written to the memory sequentially such that the memory cell is filled column by column 503. When the memory cell is filled, an interleaver address generator generates the interleaved addresses in interleaved order 505. Based on the generated interleaved address, the MSBs in the address identify the base address containing the word that should be retrieved next from memory 507. The LSBs in the address are used to identify the SISO associated with each sub-word in the next retrieved word 509. The entire word is retrieved from memory. Each sub-word is input to a MUX associated with each SISO being used. A MUX selector circuit is associated with each MUX and controls, based on the LSB's of the generated address, which of the sub-word inputs at the MUX should be routed to the associated SISO 511. While the data was written sequentially to the memory bank, words are retrieved from memory in the interleaved order. Each sub-word segment of the word is then routed to the appropriate SISO for decoding providing a contention free interleaver using a single memory.

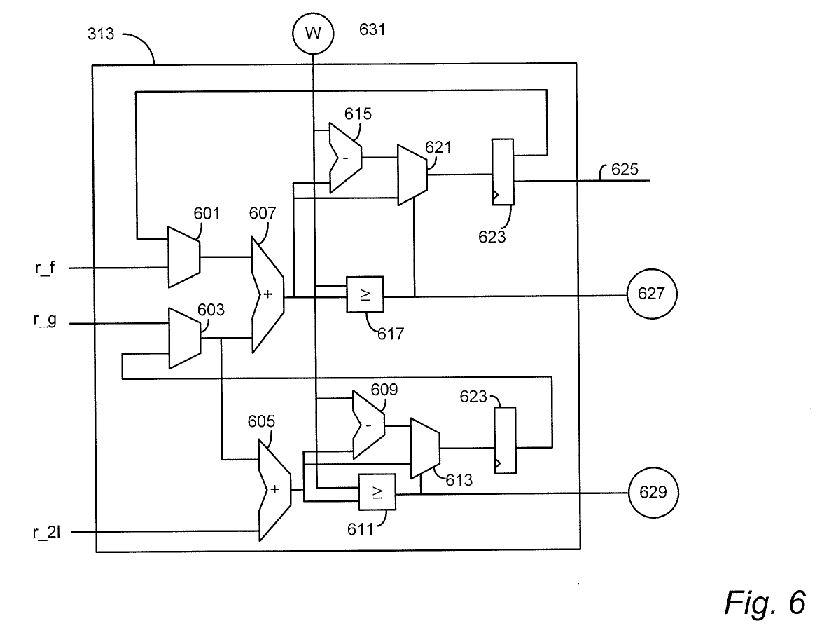

FIG. 6 shows a hardware portion of an implementation of interleaved address generator 313. For a code block of size K, the i^{th} interleaved output may be read from an address given by Equation 1.

I(i)=(f₁(i)+f₂(i)²)mod K (Equation 1)

The values of factors f₁ and f₂ may be pre-defined and stored in a table in software. The factors f₁ and f₂ are dependent on block size K. The next interleaved address may be calculated recursively using I(i) according to Equation 2.

I(i+1)=I(i)+(f₁+f₂+2*f₂i)mod K (Equation 2)

For a data length K, sectioning the data into S parallel interleavers results in a memory storage configuration where the most significant bits representing the address index are the same for each section of data, but the least significant bits relating to the SISO index are shuffled. Denoting the word length as an item width times the number of SISOs used, the address index (Addr_index) may be determined by Equation 3. The depth of the memory is represented by W and is derived from the data length K divided by the number of SISOs.

Addr_index=rⁱ₁=I(i)mod W (Equation 3)

If the number of SISOs is denoted by S, the index identifying the portion of the stored word at address I(i) may be determined according to Equation 4.

$${q}_{I}^{i} = ⌊ \frac{I ( i )}{S} ⌋ \qquad ( Equation 4 )$$

Modulo and division operations are expensive to implement in hardware. The next interleaved address (i+1) may be derived from a correct value of i using only addition and subtraction as is explained in greater detail hereinafter.

Referring to FIG. 6, the operation of the address generator 313 will now be described. A modulo operation is performed using a subtraction circuit 609, a comparator 611, and a multiplexer 613. In order to derive the next interleaved address index, a set of parameters, r_f, rg, and r_21 are used in the address generator. Input r_f, input r_g and input r_2l, are calculated in software and used as initial parameters to the address generator 313. Input r_g is initialized by software from f₁ and f₂ for the given K. In other words, input r_g is initially (f₁+f₂) mod W where W the number of words contained in extrinsic memory 303. Input r_2l is pre-calculated in software as an initial parameter based on the calculation (2*f₂i) mod W. The parameter r_f is initialized to 0.

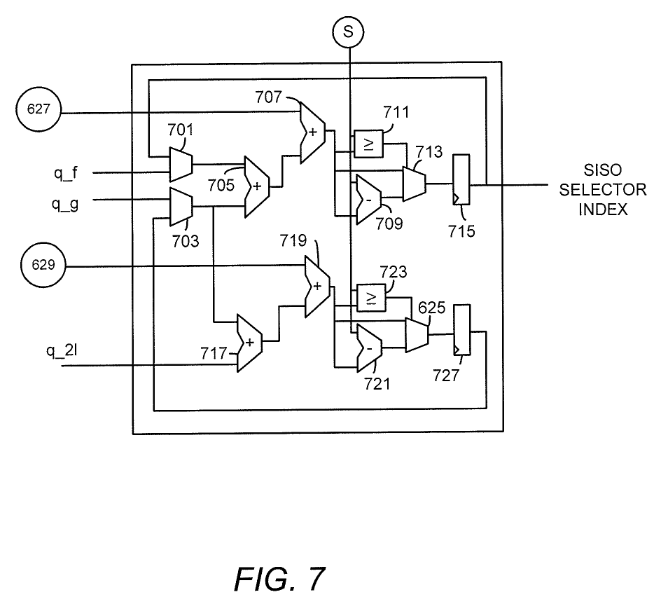

Inputs r_g and r_2l are added in adding circuit 605. The values of r_2l and r_g are combined in adding circuit 605. The value of W 631 is subtracted from the output of adding circuit 605 by subtracting circuit 609. The output of adding circuit 605 is then compared to W 631 by comparator 611. When the output of adding circuit 605 is greater or equal to W 631, comparator 611 controls MUX 613 to output the result of subtracting circuit 609. The output of MUX 613 is stored in register 623 and sent to MUX 603 for a next iteration. When the result of subtracting circuit 609 is less than W 631, comparator 611 controls MUX 613 to output the result of adding circuit 605. The output of MUX 613 is stored in register 623 and sent to MUX 603 for a next iteration. The output of comparator 611 is used as an input 629 to the SISO selection circuit whose operation will be explained with regard to FIG. 7.

MUX 601 receives as inputs, the initial parameter value r_f which is initialized in software at 0, and the contents of register 623 which contains the previously calculated interleaved memory address index 625. The previous interleaved address index is output from MUX 601 and added to the result from register 623 which is output from MUX 603 for all but the initial iteration by adding circuit 607. Subtracting circuit 615, comparator 617 and MUX 621, operate essentially identically to the operation explained hereinbefore with respect to subtraction circuit 609, comparator 611 and MUX 613. The result is the address index that is stored in register 623 and to passed to memory 303. The contents of register 623 is also directed to an input of MUX 601 and used as an input to recursively calculate the next interleaved address according to Equation 2.

FIG. 7 shows a hardware portion of an implementation of a SISO selector circuit for calculating the SISO index used to route a sub-word to the appropriate SISO. An instance of the SISO selector circuit 600 must be provided for each SISO used in the turbo decoder. For example, the turbo decoder of FIG. 3 would require four SISO selector circuits 323, 325, 327, 329. The parameters q_f, q_g and q_2l are initialized by software for the first iteration. The SISO selector circuit then recursively calculates the next sub-word index. Software initializes the value of q_2l based on the value of (2*f2) divided by the memory width W. The value q_f for each SISO selector circuit is calculated as follows: The value of q_f is initialized to a value of zero for the first SISO selector circuit. For the next SISO selector circuit, the initial q_f value is derived by software by taking the corresponding interleaved address of the first column index from FIG. 3 and dividing it by the memory depth W.

Software also initializes the q_g value for the first SISO index generator circuit by calculating

$$\frac{( {f}_{1} + {f}_{2} ) mod K}{W} .$$

The q_f initialization for the next SISO circuit is derived by taking the first interleaved address of the data of the corresponding SISO, dividing by W, and subtracting q_f value from software for that SISO selector circuit. The initialization parameter q_2l is a constant for all SISO generator circuits and is derived by calculating

$$\frac{( {f}_{1} + {f}_{2} )}{W}$$

as described above.

After the initialization of q_f and q_g, subsequent iterations use the extrinsic values calculated from the previous iteration. The calculated value of the previous iteration is selected for input by MUX 601 for the previously calculated value of q_f and MUX 603 for the previously calculated value of q_g. For each iteration, the current value of q_f and q_g are combined by adding circuit 705. The result of adding circuit 705 may or may not be incremented depending on the value of from 627 in FIG. 6 using adding circuit 707. The output value from adding circuit 707 is then compared to the number of SISOs (S) by comparator 711. The output value of adding circuit 707 is greater than S, S is subtracted from the output value of adding circuit 707 by subtraction circuit 709 and the result stored in register 715 as the next q_f value. The output stored in register 715 is also output as the SISO selector index for that SISO selector circuit.

As part of the operation to calculate the SISO selector index, the value of q_2l is also combined with the selected q_g value from MUX 703 by adding circuit 717. The resulting value from adding circuit 717 is incremented based on the input 629 from FIG. 6 in adding circuit 719. The output of adding circuit 719 is compared to the number of SISOs (S) by comparator 723. If the output of adding circuit 719 is greater than S, S is subtracted from the output of adding circuit 719 by subtracting circuit 721 and stored in register 727. The result stored in register 727 is used as the next value of q_g at the next iteration.

Although features and elements are described above in particular combinations, each feature or element can be used alone without the other features and elements or in various combinations with or without other features and elements. The methods or flow charts provided herein may be implemented in a computer program, software, or firmware incorporated in a computer-readable storage medium for execution by a general purpose computer or a processor. Examples of computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

A processor in association with software may be used to implement a radio frequency transceiver for use in a wireless transmit receive unit (WTRU), user equipment (UE), terminal, base station, radio network controller (RNC), or any host computer. The WTRU may be used in conjunction with modules, implemented in hardware and/or software, such as a camera, a video camera module, a videophone, a speakerphone, a vibration device, a speaker, a microphone, a television transceiver, a hands free headset, a keyboard, a Bluetooth® module, a frequency modulated (FM) radio unit, a liquid crystal display (LCD) display unit, an organic light-emitting diode (OLED) display unit, a digital music player, a media player, a video game player module, an Internet browser, and/or any wireless local area network (WLAN) or Ultra Wide Band (UWB) module.

What is claimed is:

1. A method of de-interleaving encoded data using a single memory comprising:
receiving encoded interleaved data;
storing the encoded interleaved data in sequential order in the single memory;
generating an interleaved address;
identifying a column in the single memory containing interleaved data associated with the generated interleaved address based on the most significant bits (MSBs) in the generated interleaved address;
retrieving contents of an identified column in the single memory;
forwarding a plurality of sub-words contained in the identified column, to a plurality of multiplexers (MUXs), wherein each of the plurality of MUXs is associated with each of a plurality of soft-in/soft-out (SISO) decoders;
identifying a sub-word corresponding to one of the plurality of SISO decoders based on the least significant bits (LSBs) of the interleaved address; and
routing the sub-word to a corresponding SISO decoder associated with the sub-word.

2. The method of claim 1, wherein a number of columns in the single memory is a number of bits in a data block divided by the plurality of SISO decoders being used.

3. The method of claim 1, wherein a width of each word in the single memory is equal to a number of encoded bits associated with a single data bit times a number of SISO decoders being used.

4. The method of claim 1, wherein a width of each sub-word is equal to the number of encoded bits associated with a single data bit.

5. The method of claim 1, wherein a number of SISO decoders being used is a power of two.

6. The method of claim 1 further comprising:
writing each sub-word of the column in the single memory using a write enable for each sub-word.

7. A wireless transmit/receive unit (WTRU) for receiving encoded data in wireless communications, comprising:
a receiver configured to receive encoded interleaved data;
a single memory configured to store the encoded interleaved data in an order it is received in the single memory;
an interleaved address generator configured to generate an interleaved address, wherein the interleaved address identifies a column in the single memory on the most significant bits (MSBs) in the interleaved address;
a processor configured to retrieve contents of an identified column in the single memory;
a plurality of SISO decoders;
a plurality of multiplexers coupled between the single memory and the plurality of SISO decoders;
the processor further configured to forward a plurality of sub-words contained in the contents of the identified column, to the plurality of multiplexers (MUXs), wherein each of the plurality of MUXs is associated with one of the plurality of SISO decoders;
the processor further configured to identify a sub-word corresponding to one of the plurality of SISO decoders based on the least significant bits (LSBs) of the interleaved address; and
the processor further configured to route the sub-word to a corresponding SISO by controlling the output of the MUXs.

8. The WTRU of claim 7, wherein a number of columns in the single memory is a number of bits in a data block divided by a number of SISO decoders being used.

9. The WTRU of claim 7, wherein a width of a word in the single memory is equal to a number of encoded bits associated with a single data bit times a number of SISO decoders being used.

10. The WTRU of claim 7, wherein a width of each of the plurality of sub-words is equal to a number of encoded bits associated with a single data bit.

11. The WTRU of claim 7, wherein a number of SISO decoders being used is a power of two.

12. The WTRU of claim 7 further comprising:
a plurality of write enables coupled to each memory location in the single memory where a beginning of each of the plurality of sub-words is stored.

13. An integrated circuit configured for use in a turbo decoder for decoding received encoded data in wireless communications, comprising:
a single memory;
an interleaved address generator, wherein the output of the interleaved address generator is an address in the single memory, wherein the most significant digits of the address in the single memory represents a column of the single memory, and the least significant bits of the address in the single memory represents an index that indicates one of a plurality of soft-in/soft-out (SISO) decoders associated with one of a plurality of sub-words contained in the column of the single memory;
a SISO selector circuit configured to route one of the plurality of sub-words contained in the column of the single memory to an associated SISO decoder based on the least significant bits of the output of the interleaved address generator.

14. The integrated circuit of claim 13, wherein the output of the interleaved address generator is used to order a second plurality of sub-words as the plurality of sub-words are written to the single memory as extrinsic data in an iteration of the turbo decoder.

15. The integrated circuit of claim 13, wherein the SISO selector circuit is configured to route the first plurality of sub-words contained in the column of the single memory to a number of SISO decoders that is a power of 2.
